(19) United States
(12) Patent Application Publication
(10) Pub. No.: US 2014/0268983 A1
(43) Pub. Date: Sep. 18, 2014

(54) OTPROM ARRAY WITH LEAKAGE CURRENT CANCELATION FOR ENHANCED EFUSE SENSING

(71) Applicant: GLOBALFOUNDRIES, INC., Grand Cayman (KY)

(72) Inventors: Juergen Boldt, Dresden (DE); Andreas Rudnick, Malschwitz (DE)

(73) Assignee: GLOBALFOUNDRIES, INC., Grand Cayman (KY)

(21) Appl. No.: 13/834,477

(22) Filed: Mar. 15, 2013

(51) Int. Cl. G11C 17/18

(52) U.S. Cl. CPC G11C 17/18
USPC 365/96

(57) ABSTRACT

Disclosed herein are memory cell arrays and methods for operating memory cell arrays. In one embodiment, a memory cell array includes a plurality of bitcells, a first bitline, a second bitline, a first wordline and a second wordline. The bitcells are arranged into rows and columns and each include a first transistor, a second transistor, and a fuse with a first end and a second end. The second transistor is selectively operable to couple the first end of the fuse to a ground. The first bitline is coupled to the first transistor of each of the bitcells of one column. The second bitline is coupled to the second end of the fuse of each of the bitcells of the column. The first transistor of each of the bitcells of the column is selectively operable to couple the first end of the fuse to the first bitline.

### TECHNICAL FIELD

The present disclosure relates to memory cell arrays. More particularly, the present disclosure relates to one-time programmable memory cell arrays that exhibit reduced leakage current.

### BACKGROUND

A one-time programmable read-only memory (OTPROM) is a non-volatile memory structure that may be programmed after the memory is manufactured. The OTPROM retains a programmed memory state even when no power is provided to the OTPROM. An OTPROM memory cell array typically includes one bitcell per data bit to be stored. Each row of bitcells in the OTPROM array may be coupled to a signal line known as a wordline. Each column of bitcells in the OTPROM array may be coupled to a signal line known as a bitline.

In a typical OTPROM bitcell, a fuse or an antifuse may be used to permanently set the value of a bitcell. Burning a fuse causes the resistance across the fuse to increase or causes the circuit to open across the fuse, while programming an antifuse causes the resistance across the fuse to decrease or causes the circuit to close across the fuse. The logic state sensed or read from an OTPROM bitcell may be based on whether the fuse of the bitcell has burned. For example, each OTPROM bitcell with an unburned fuse may indicate a particular binary value (e.g., logic state low, logic state high), while each OTPROM bitcell with a burned fuse may indicate the opposite binary value. Therefore, an array of OTPROM bitcells may be programmed by burning the fuses of the OTPROM bitcells whose value is to be different from the default binary value.

Large OTPROM arrays typically experience leakage current that interferes with the ability of a sense amplifier to detect the state of a bitcell. Leakage current is current that flows through transistors that are turned off. A typical OTPROM array includes one bitline to which a fuse programming voltage source and a sense amplifier are coupled. The voltage applied to the bitline during sensing results in leakage current through the bitcells that are not currently activated. Such leakage current increases the current detected by the sense amplifier and may result in an incorrect determination of the fuse state of the activated bitcell.

Accordingly, it is desirable to provide an OTPROM array that exhibits reduced leakage current when sensing the state of a bitcell fuse. Furthermore, other desirable features and characteristics of the semiconductor fabrication methods and systems will become apparent from the subsequent detailed description and the appended claims, taken in conjunction with the accompanying drawings, brief summary, and this background.

### BRIEF SUMMARY

Disclosed herein are memory cell arrays and methods for operating memory cell arrays. In one embodiment, a memory cell array includes a plurality of bitcells, a first bitline, and a second bitline. The bitcells are arranged into rows and columns and each include a first transistor, a second transistor, and a fuse with a first end and a second end. The second transistor is selectively operable to couple the first end of the fuse to a ground. The first bitline is coupled to the first transistor of each of the bitcells of one column. The second bitline is coupled to the second end of the fuse of each of the bitcells of the column. The first transistor of each of the bitcells of the column is selectively operable to couple the first end of the fuse to the first bitline.

In another exemplary embodiment, a method of operating a memory cell array includes coupling a first end of a fuse of a bitcell to a first bitline during a read operation, coupling a second bitline to ground during the read operation, and enabling a sense amplifier during the read operation. The second bitline is coupled to a second end of the fuse and the sense amplifier is coupled to the first bitline.

In another exemplary embodiment, a memory cell array includes a plurality of bitcells, a first bitline, a second bitline, a first wordline, a second wordline, and a bitline driver. The plurality of bitcells are arranged into a plurality of rows and a plurality of columns and each include a first transistor, a second transistor, and a fuse with a first end and a second end. The second transistor is selectively operable to couple the first end of the fuse to a ground. The first bitline is coupled to the first transistor of each of the plurality of bitcells of one column of the plurality of columns. The second bitline is coupled to the second end of the fuse of each of the plurality of bitcells of the one column. The first wordline is coupled to the first transistor of each of the plurality of bitcells of one row of the plurality of rows of bitcells for selectively coupling the first end of the fuse to the first bitline. The second wordline is coupled to the second transistor of each of the plurality of bitcells of the one row of bitcells for selectively coupling the first end of the fuse with the ground. The bitline driver is coupled to the second bitline and includes a first transistor and a second transistor. The first transistor of the bitline driver is selectively operable to apply a programming voltage to the second bitline and the second transistor of the bitline driver is selectively operable to couple the second bitline to the ground. The first transistor of each of the plurality of bitcells of the one column is selectively operable to couple the first end of the fuse to the first bitline.

### BRIEF DESCRIPTION OF THE DRAWINGS

Exemplary embodiments of the present disclosure will hereinafter be described in conjunction with the following drawing figures, wherein like numerals denote like elements, and wherein:

FIG. 1 is a block diagram of an OTPROM memory cell array in accordance with some embodiments;

FIG. 2 is a circuit diagram of a portion of the OTPROM memory cell array of FIG. 1 in accordance with some embodiments; and

FIG. 3 is a timing diagram of various signals of the OTPROM memory cell array of FIG. 1 in accordance with some embodiments.

### DETAILED DESCRIPTION

The following detailed description of the invention is merely illustrative in nature and is not intended to limit the embodiments of the subject matter or the application and uses of such embodiments. As used herein, the word “exemplary” means “serving as an example, instance or illustration.” Any implementation described herein as exemplary is not necessarily to be construed as preferred or advantageous over other implementations. Furthermore, there is no intention to be bound by any expressed or implied theory presented in the preceding Technical Field, Background, Brief Summary or the following Detailed Description

The following description refers to elements or nodes or features being “connected or “coupled” together. As used herein, unless expressly stated otherwise, “coupled” means that one element/node/feature is directly joined to (or directly or indirectly communicates with) another element/node/feature, and not necessarily mechanically. Likewise, unless expressly stated otherwise, “connect” means that one element/node feature is directly joined to (or directly communicates with) another element/node/feature, and not necessarily mechanically.

FIG. 1 illustrates a block diagram of an OTPROM memory cell array 100 according to some embodiments. The memory cell array 100 includes a plurality of bitcells 102, a wordline driver 104, a plurality of bitline drivers 106, and a plurality of sense amplifiers 107. The bitcells 102 are arranged in rows and columns. Each bitcell 102 is coupled to the wordline driver 104 by one of a plurality of write wordlines 108 and one of a plurality of read wordlines 110. The wordlines 108 and 110 provide access to the row of bitcells 102 in the memory cell array 100. For example, the read wordlines 110 may be enabled (e.g., provided with a voltage) to select the respective row of the bitcells 102 for reading. Similarly, the write wordlines 108 may be enabled to select the respective row of bitcells 102 for programming in cooperation with a bitline.

Each bitcell 102 is also coupled to one of the bitline drivers 106 by one of a plurality of write bitlines 112 and is coupled to one of the sense amplifiers 107 by one of a plurality of read bitlines 116. The bitlines 112 and 116 provide access to a column of bitcells 102 in the memory cell array 100. For example, one of the plurality of bitline drivers 106 is coupled to one of the write bitlines 112 to both provide a programming current to a selected bitcell 102 during a write operation and to pass a sensing current to ground during a read operation, as will be described below. In some embodiments, the read bitlines 116 have dimensions that are less than required dimensions for carrying a burning current for burning the fuse. The smaller dimensions permit a more compact memory cell array 100.

FIG. 2 is an illustration of a portion 200 of the memory cell array 100 according to some embodiments. The portion 200 includes one of the bitcells 102, one of the bitline drivers 106 coupled to the bitcell 102 by one of the write bitlines 112, and one of the sense amplifiers 107 coupled to the bitcell 102 by one of the read bitlines 116.

For the exemplary embodiments described herein, the bitcell 102, the bitline driver 106, and the sense amplifier 107 are fabricated on an appropriate semiconductor substrate. These semiconductor-based circuits may be formed using well known techniques and process steps (e.g., photolithography, doping, etching, patterning, material growth, material deposition, and the like) that will not be described in detail here. In some embodiments, the semiconductor material used is silicon. In some alternative embodiments, the semiconductor material may include germanium, gallium arsenide, or the like. The semiconductor material may be used to fabricate an N-type metal-oxide-semiconductor (NMOS) transistor or P-type metal-oxide-semiconductor (PMOS) transistor. The NMOS transistors include a source, a drain, a gate, and a bulk that is coupled to a ground, while the PMOS transistors include a source, a drain, a gate, and a bulk that is coupled to a power supply.

The bitcell 102 shown in FIG. 2 includes a first transistor 210, a second transistor 212, and a fuse 214. In the example provided, the transistors 210 and 212 are NMOS transistors. The drain of the first transistor 210 is coupled to the sense amplifier 107 by the read bitline 116. The source of the first transistor 210 is coupled to a first end of 216 the fuse 214 and the drain of the second transistor 212. The gate of the first transistor 210 is coupled to the wordline driver 104 by the read wordline 110. The read wordline 110 may be enabled to turn on the first transistor 210 and selectively couple the sense amplifier 107 to the first end 216 of the fuse 214 for sensing the state of the bitcell 102, as will be described below. A second end 218 of the fuse 214 is coupled to the bitline driver 106 by the write bitline 112.

The source of the second transistor 212 is coupled to ground. The gate of the second transistor 212 is coupled to the wordline driver 104 by the write wordline 108. The write wordline 108 may be enabled to turn on the second transistor 212 and selectively couple the first end 216 of the fuse 214 with ground for burning the fuse, as will be described below. It should be appreciated that the first and second transistors 210 and 212 may be any devices that selectively couple the first end 216 of the fuse 214 to the read bitline 116 and ground, respectively.

In some embodiments, the fuse 214 is a metal fuse device that burns when a current through the fuse 214 exceeds a threshold amount. In the example provided, the fuse 214 is an electronically programmable fuse where the first end 216 is a cathode and the second end 218 is an anode. It should be appreciated that any suitable fuse, antifuse, or other one-time programmable device may be utilized.

The bitline driver 106 includes a first transistor 220, a second transistor 222, a burn port 224, a programming voltage port 226, and a bitline zeroing port 228. In the example provided, the first transistor 220 is a PMOS transistor and the second transistor 222 is an NMOS transistor. The source of the first transistor 220 is coupled to the programming voltage port 226, the gate of the first transistor 220 is coupled to the burn port 224, and the drain of the first transistor 220 is coupled to the write bitline 112. The burn port 224 may be enabled to selectively couple the programming voltage port 226 to the write bitline 112 and permit a burning current to flow, as will be described below.

The source of the second transistor 222 is coupled to ground, the gate of the second transistor 222 is coupled to the bitline zeroing port 228, and the drain of the second transistor 222 is coupled to the write bitline 112. The bitline zeroing port 228 may be enabled to selectively couple the write bitline 112 with ground. Accordingly, a voltage V_{DS} across the drain and source of the second transistors 212 is substantially zero volts for inactivated bitcells 102. The zero volt V_{DS} substantially eliminates current leakage through the inactive bitcells 102 and permits a large number of bitcells 102 per bitline.

The sense amplifier 107 has an enable port 230, an input port 232, an output port 234, and a voltage input port 236. The sense amplifier 107 may be of any suitable type and have any suitable transistor configuration. In the example provided, the sense amplifier is a current sense amplifier. The enable port 230 may be enabled to sense the state of a bitcell 102 of the column of bitcells 102 coupled to the sense amplifier 107 by the read bitline 116. The input port 232 is coupled to the read bitline 116 for sensing the state of the bitcells 102 by detecting the current flow through the read bitline 116. The output port 234 generates a signal based on the logic state of the sensed bitcell 102, as will be described below.

FIG. 3 is a timing diagram of various signals of the memory cell array 100 of FIG. 1. The timing diagram illustrates exemplary signal values during each of a burn fuse operation 302, a first read bitcell operation 304 in which the fuse 214 is unburned, and a second read bitcell operation 306 in which the fuse 214 is burned. The burn fuse operation 302 is initiated by enabling the write wordline 108 and the burn fuse port 224 of the bitline driver 106. Accordingly, the first transistor 220 of the bitline driver 106 and the second transistor 212 of the bitcell 102 are on, and the write bitline 112 is coupled to the programming voltage port 226. A burning current 310 flows from the programming voltage port 226 through the first transistor 220 of the bitline driver 106, through the write bitline 112, through the fuse 214, and through the second transistor 212 of the bitcell 102 to ground. The burning current 310 is maintained during the burn fuse operation 302 to burn the fuse 214 and permanently change the logic state of the bitcell 102.

The first and second read bitcell operations 304 and 306 are initiated by enabling the enable port 230 of the sense amplifier 107, the read wordline 110, and the bitline zeroing port 228 of the bitline driver 106. Accordingly, the second transistor 222 of the bitline driver 106 and the first transistor 210 of the bitcell 102 are on. During the first read bitcell operation 304, current flows from the input port 232 of the sense amplifier through the read bitline 116, through the first transistor of the bitcell 102, through the fuse 214, through the write bitline 112, and through the second transistor 222 of the bitline driver 106 to ground. The voltage of the read bitline 116 is substantially equal to the voltage drop across the fuse 214 and the transistors 210 and 222. During the second read bitcell operation 306, little or no current flows through the fuse 214, and the voltage of the read bitline 116 is substantially the same as V_{DD} applied to the voltage input port 236 of the sense amplifier 107.

The memory cell array provided has several beneficial attributes. For example, the write bitline and the second end of each fuse in a bitline is coupled to ground during sensing to restrict leakage current from inactive bitcells. Additionally, the leakage current restriction permits implementation of large bitcell transistors between the first end of the fuse and ground for burning. Low threshold voltage transistors may also be incorporated to reduce the bitcell area. For example, the first transistor 210 in bitcell 102 may be small (e.g., 1/10×width/length ratio) compared to the second transistor 212. Accordingly, the increase of size of the bitcell may be increased only slightly with the additional transistor 210.

Thin lines may also be incorporated for the read bitlines because the read bitlines need only carry sensing current, and not the burning current used to burn the fuse. Furthermore, the first transistor of the bitcell acts as a current source and the impact of voltage drops (IR-drops, Cross-talk) on the read bitline are reduced.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. A memory cell array comprising:
a plurality of bitcells arranged into a plurality of rows and a plurality of columns and that each include a first transistor, a second transistor, and a fuse with a first end and a second end, wherein the second transistor is selectively operable to couple the first end of the fuse to a ground;
a first bitline coupled to the first transistor of each of the plurality of bitcells of one column of the plurality of columns; and
a second bitline coupled to the second end of the fuse of each of the plurality of bitcells of the one column, and
wherein the first transistor of each of the plurality of bitcells of the one column is selectively operable to couple the first end of the fuse to the first bitline.

2. The memory cell array of claim 1 further comprising a bitline driver coupled to the second bitline and including a first transistor and a second transistor, wherein the first transistor of the bitline driver is selectively operable to apply a programming voltage to the second bitline and the second transistor of the bitline driver is selectively operable to couple the second bitline to the ground.

3. The memory cell array of claim 2 wherein the first transistor of the bitline driver is a PMOS transistor with a source coupled to the programming voltage and a drain coupled to the second bitline, and wherein the second transistor of the bitline driver is an NMOS transistor with a source coupled to ground and a drain coupled to the second bitline.

4. The memory cell array of claim 1 further comprising a sense amplifier coupled to the first bitline to detect a state of one of the plurality of bitcells.

5. The memory cell array of claim 4 wherein the sense amplifier is a current sense amplifier that outputs a logic state of the bitcell based on the current through the first bitline and the fuse.

6. The memory cell array of claim 1 further comprising a first wordline coupled to the first transistor of each of the plurality of bitcells of one row of the plurality of rows of bitcells for selectively coupling the first end of the fuse to the first bitline.

7. The memory cell array of claim 6 further comprising a second wordline coupled to the second transistor of each of the plurality of bitcells of the one row of bitcells for selectively coupling the first end of the fuse with the ground.

8. The memory cell array of claim 1 wherein the fuse is an electronically programmable fuse, the first end of the fuse is a cathode of the electronically programmable fuse, and the second end of the fuse is an anode of the electronically programmable fuse.

9. The memory cell array of claim 1 wherein the first bitline has dimensions that are smaller than required dimensions for carrying a burning current of the fuse.

10. The memory cell array of claim 1 wherein the first transistor of each of the plurality of bitcells of the one column is an NMOS transistor with a source coupled to the first end of the fuse and a drain coupled to the first bitline, and wherein the second transistor of each of the plurality of bitcells is an NMOS transistor with a source coupled to ground and a drain coupled to the first end of the fuse.

11. A method of operating a memory cell array, the method comprising:
coupling a first end of a fuse of a bitcell to a first bitline during a read operation;
coupling a second bitline to ground during the read operation, wherein the second bitline is coupled to a second end of the fuse; and
enabling a sense amplifier during the read operation, wherein the sense amplifier is coupled to the first bitline.

12. The method of claim 11 wherein coupling the first end of the fuse to the first bitline further comprises enabling a read wordline with a wordline driver to turn on a first transistor of the bitcell, and wherein coupling the second bitline to ground further comprises enabling a zeroing port of a bitline driver to turn on a second transistor of the bitline driver.

13. The method of claim 11 further comprising:
coupling the first end of the fuse of the bitcell to ground during a burning operation; and
coupling the second bitline to a programming voltage during the burning operation.

14. The method of claim 13 wherein coupling the first end of the fuse to ground further comprises enabling a write wordline with a wordline driver to turn on a second transistor of the bitcell, and wherein coupling the second bitline to the programming voltage further comprises enabling a burn port of a bitline driver to turn on a first transistor of the bitline driver.

15. A memory cell array comprising:
a plurality of bitcells arranged into a plurality of rows and a plurality of columns and that each include a first transistor, a second transistor, and a fuse with a first end and a second end, wherein the second transistor is selectively operable to couple the first end of the fuse to a ground;
a first bitline coupled to the first transistor of each of the plurality of bitcells of one column of the plurality of columns;
a second bitline coupled to the second end of the fuse of each of the plurality of bitcells of the one column;
a first wordline coupled to the first transistor of each of the plurality of bitcells of one row of the plurality of rows of bitcells for selectively coupling the first end of the fuse to the first bitline;
a second wordline coupled to the second transistor of each of the plurality of bitcells of the one row of bitcells for selectively coupling the first end of the fuse with the ground; and
a bitline driver coupled to the second bitline and including a first transistor and a second transistor, wherein the first transistor of the bitline driver is selectively operable to apply a programming voltage to the second bitline and the second transistor of the bitline driver is selectively operable to couple the second bitline to the ground, and
wherein the first transistor of each of the plurality of bitcells of the one column is selectively operable to couple the first end of the fuse to the first bitline.

16. The memory cell array of claim 15 wherein the first transistor of the bitline driver is a PMOS transistor with a source coupled to the programming voltage and a drain coupled to the second bitline, and wherein the second transistor of the bitline driver is an NMOS transistor with a source coupled to ground and a drain coupled to the second bitline.

17. The memory cell array of claim 15 wherein the fuse is an electronically programmable fuse, the first end of the fuse is a cathode of the electronically programmable fuse, and the second end of the fuse is an anode of the electronically programmable fuse.

18. The memory cell array of claim 15 wherein the first bitline has dimensions that are smaller than required dimensions for carrying a burning current of the fuse.

19. The memory cell array of claim 15 wherein the first transistor of each of the plurality of bitcells of the one column is an NMOS transistor with a source coupled to the first end of the fuse and a drain coupled to the first bitline, and wherein the second transistor of each of the plurality of bitcells is an NMOS transistor with a source coupled to ground and a drain coupled to the first end of the fuse.

20. The memory cell array of claim 15 further comprising a current sense amplifier coupled to the first bitline to output a logic state of the bitcell based on the current through the first bitline and the fuse.
